(19) United States
(12) Patent Application Publication
(10) Pub. No.: US 2026/0096307 A1
(43) Pub. Date: Apr. 2, 2026

(54) DISPLAY DEVICE AND ELECTRONIC DEVICE

(71) Applicant: Samsung Display Co., Ltd., Yongin-Si (KR)

(72) Inventors: Aeran SONG, Yongin-si (KR); So Young KOO, Yongin-si (KR); JONGDO KEUM, Yongin-si (KR); Eok Su KIM, Yongin-si (KR); Hyung Jun KIM, Yongin-si (KR); Geun Chul PARK, Yongin-si (KR); Joon Seok PARK, Yongin-si (KR)

(21) Appl. No.: 19/241,458

(22) Filed: Jun. 18, 2025

(30) Foreign Application Priority Data
Sep. 27, 2024 (KR) 10-2024-0132053

(51) Int. Cl. H10K 59/124; H10K 59/131; H10K 102/00

(52) U.S. Cl. CPC H10K 59/124; H10K 59/131; H10K 2102/351

(57) ABSTRACT

A display device according to an embodiment comprises a substrate, a semiconductor layer disposed on the substrate, a first insulating layer, a first organic layer, a second insulating layer, and a second organic layer sequentially disposed on the semiconductor layer, a first electrode disposed on the second organic layer, a partition wall disposed on the first electrode and including a pixel opening, and a light emitting layer disposed in the pixel opening, wherein the second insulating layer includes a plurality of first openings, the plurality of first openings are filled with the second organic layer, and the thickness of the first organic layer and the second organic layer is about 1.5 μm to about 3 μm.

### CROSS-REFERENCE TO RELATED APPLICATION

This application claims priority to and the benefit of Korean Patent Application No. 10-2024-0132053 filed at the Korean Intellectual Property Office on Sep. 27, 2024, the entire contents of which are incorporated herein by reference.

### BACKGROUND

### 1. Field of the Inventive Concept

The present disclosure relates to a display device and an electronic device.

### 2. Description of the Related Art

A display device is an apparatus for visually displaying images. Display devices may be used as displays of small products such as mobile phones or may be used as displays of large products such as televisions.

The display device includes a plurality of sub-pixels that receive an electric signal and emit light to display an image to the outside. Each sub-pixel may include a light emitting device. For example, an organic light emitting display device includes a light emitting diode (LED) as a light emitting device. Generally, a light emitting display device includes a thin-film transistor and an LED on a substrate, and the LED emits light by itself.

Recently, as the use of display devices has diversified, various designs have been attempted to improve the quality of display apparatuses.

### SUMMARY

The embodiments attempt to provide a display device capable of preventing pixel shrinkage caused by gas by patterning an insulating layer protecting an additional wiring layer for high-resolution implementation, and controlling the thickness of an organic layer for planarization to discharge gas that may be generated by the organic layer.

A display device according to an embodiment comprises a substrate, a semiconductor layer disposed on the substrate, a first insulating layer, a first organic layer, a second insulating layer, and a second organic layer sequentially disposed on the semiconductor layer, a first electrode disposed on the second organic layer, a partition wall disposed on the first electrode and including a pixel opening, and a light emitting layer disposed in the pixel opening, wherein the second insulating layer includes a plurality of first openings, the plurality of first openings are filled with the second organic layer, and the thickness of the first organic layer and the second organic layer is from about 1.5 μm to about 3 μm.

The semiconductor layer may comprise a channel region, a first region disposed on one side of the channel region, and a second region disposed on another side of the channel region.

The display device may include a first wiring layer disposed under the first organic layer and connected to the first region, and a second wiring layer disposed on the first organic layer and connected to the first wiring layer.

At least some of the plurality of first openings may overlap the first region and the second region.

At least two of the plurality of first openings may overlap the channel region.

A width of one of the plurality of first openings in a cross-sectional view may be greater than the lengths of the first region and the second region.

A width of one of the plurality of first openings in a cross-sectional view may have a size from about 20% to about 23% of the width of the pixel opening.

The first insulating layer and the second insulating layer may include silicon nitride.

The semiconductor layer may further include a gate insulating film disposed on the channel region, an oxygen supply layer disposed on the gate insulating film, and a gate electrode disposed on the oxygen supply layer.

The first wiring layer and the second wiring layer may include at least one of Cu, Ti, Al, Pt, Ag, Mg, Ni, or W.

The semiconductor layer may include an oxide semiconductor.

The semiconductor layer may include at least one of an In-Zn-based oxide, an In-Ga-based oxide, an Sn-Zn-based oxide, an In-Sn-Zn-based oxide, an In-Ga-Zn-based oxide, an Sn-Ga-Zn-based oxide, or an In-Sn-Ga-Zn-based oxide.

A display device according to an embodiment comprises a substrate, a semiconductor layer disposed on the substrate, a first wiring layer, a second wiring layer, a first organic layer, a second organic layer, and an insulating layer disposed on the semiconductor layer, a first electrode disposed on the first organic layer, a partition wall disposed on the first electrode and including an opening, and a light emitting layer disposed in the pixel opening, wherein the semiconductor layer includes a channel region, and a first region disposed on one side of the channel region and a second region disposed on another side of the channel region, the first wiring layer is connected to the first region under the first organic layer, the second wiring layer is connected to the first wiring layer, and the thickness of the first organic layer and the second organic layer is about 1.5 μm to about 3 μm.

The insulating layer may comprise a first insulating layer and a second insulating layer, the second insulating layer may include a plurality of first openings, and the plurality of first openings may be filled with the second organic layer.

The first insulating layer may be disposed between the semiconductor layer and the first organic layer, and the second insulating layer may be disposed between the first organic layer and the second organic layer.

At least some of the plurality of first openings may overlap the first region and the second region.

At least two of the plurality of first openings may overlap the channel region.

A width of one of the plurality of first openings in a cross-sectional view may be greater than the lengths of the first region and the second region.

A width of one of the plurality of first openings in a cross-sectional view may have a size from about 20% to about 23% of the width of the pixel opening.

An electronic device according to an embodiment comprises a memory, a processor executing an application stored in the memory, and a display device comprising a display module outputting video information provided by the application, wherein the display device comprising: a substrate, a semiconductor layer disposed on the substrate, a first insulating layer, a first organic layer, a second insulating layer, and a second organic layer sequentially disposed on the semiconductor layer, a first electrode disposed on the second insulating layer, a partition wall disposed on the first electrode and including a pixel opening, and a light emitting layer disposed in the pixel opening, wherein the second insulating layer includes a plurality of first openings, the plurality of first openings are filled with the second organic layer, and the thickness of the first organic layer and the second organic layer is from about 1.5 μm to about 3 μm.

According to embodiments, by forming an opening by patterning an insulating layer for protecting a wiring layer, it is possible to efficiently discharge gas generated in an organic layer to the outside, and reduce the amount of gas generated by controlling the thickness of the organic layer. This structure enables the provision of a display device that reduces pixel shrinkage caused by gas by preventing gas from moving to the electrode layer.

### BRIEF DESCRIPTION OF THE DRAWINGS

FIG. 1 is a schematic cross-sectional view of a display device according to an embodiment.

FIG. 2 is a cross-sectional view showing a gas discharge structure of a display device according to an embodiment.

FIG. 3 is a graph showing the performance of a semiconductor layer of a display device according to an embodiment.

FIG. 4 is a table showing the design value of an opening area of a display device according to an embodiment.

FIG. 5A is an image showing the design value of an opening area of a display device according to an embodiment.

FIG. 5B is an image showing actual pixel illumination of a display device according to an embodiment.

FIG. 6 is a graph showing the luminance reduction ratio of a red pixel of a display device according to an embodiment.

FIG. 7 is a table showing improvements in pixel shrinkage of a display device according to an embodiment.

FIG. 8 is a flowchart showing a method of manufacturing a display device according to an embodiment.

FIG. 9 illustrates a block diagram of an electronic device according to an embodiment.

FIG. 10 illustrates schematic diagrams of electronic devices according to various embodiments.

### DETAILED DESCRIPTION

The present disclosure will be described in detail hereinafter with reference to the accompanying drawings in which embodiments of the present disclosure are shown. As those skilled in the art would realize, the described embodiments may be modified in various different ways all without departing from the spirit or scope of the present disclosure.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the disclosure is not limited to the illustrated sizes and thicknesses. In the drawings, the thicknesses of layers and regions are exaggerated for clarity. In the drawings, to facilitate understanding and ease of description, the thicknesses of some layers and regions may be exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is referred to as being “on” or “above” a reference element, it may be disposed above or below the reference element, and it may not necessarily be referred to as being disposed “on” or “above” it in a direction opposite to gravity.

In addition, unless explicitly stated to the contrary, the word “comprise” and variations such as “comprises” and “comprising” should be understood to imply the inclusion of stated elements but not the exclusion of any other elements.

In addition, the phrase “in a plan view” means a view from a position above the object (e.g., from the top), and the phrase “in a cross-sectional view” means a view of a cross-section of the object which is vertically cut from the side.

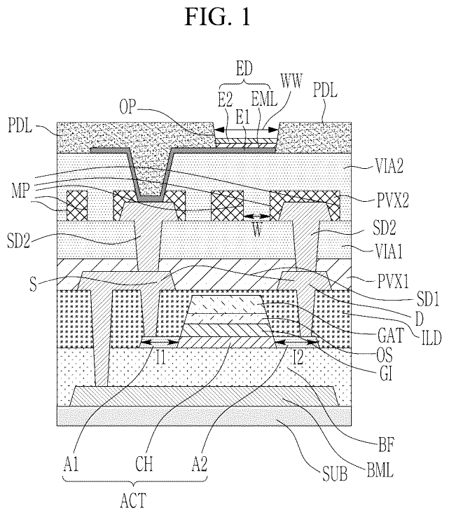

First, a display device according to an embodiment will be described with reference to FIG. 1 as follows. FIG. 1 illustrates a display device according to an embodiment.

As shown in FIG. 1, a display device according to an embodiment may include a substrate SUB, a lower metal layer BML disposed on the substrate SUB, a buffer layer BF disposed on the lower metal layer BML, a semiconductor layer ACT disposed on the buffer layer BF, a gate electrode GAT overlapping the semiconductor layer ACT, and a first wiring layer SD1 connected to the semiconductor layer ACT. The first wiring layer SD1 may include a source electrode S and a drain electrode D.

The substrate SUB may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate.

The substrate SUB may be a rigid substrate, or a flexible substrate that is bendable, foldable, or rollable. The substrate SUB may be single-layered or multi-layered. In the substrate SUB, at least one base layer including a polymer resin and at least one inorganic layer may be alternately stacked.

The lower metal layer BML may be disposed to overlap the semiconductor layer ACT and may have a width wider than that of the semiconductor layer ACT. The lower metal layer BML may be connected to the source electrode S which is one electrode connected to a first region A1 of the semiconductor layer ACT. The lower metal layer BML may be connected to the first wiring layer SD1. The lower metal layer BML may be disposed under the channel region CH of the semiconductor layer ACT and may block light incident on the semiconductor layer ACT to stabilize the operating characteristics of the semiconductor layer ACT.

The buffer layer BF may be disposed between the substrate SUB and the semiconductor layer ACT and may block impurities from the substrate SUB from flowing into the semiconductor layer ACT to improve the characteristics of the semiconductor layer ACT. In addition, the buffer layer BF may planarize the substrate SUB and relieve stress on the semiconductor layer ACT formed on the buffer layer BF. The buffer layer BF may have a single-layer or multi-layer structure. The buffer layer BF may include an inorganic insulating material such as silicon nitride (SiNx), silicon oxide (SiOx), or silicon oxynitride (SiOxNy).

The semiconductor layer ACT may include the first region A1, the channel region CH, and a second region A2. The first region A1 and the second region A2 may be disposed on each side of the channel region CH of the semiconductor layer ACT. The semiconductor layer ACT may be formed of an oxide semiconductor. The oxide semiconductor may include at least one of one-component metal oxides such as indium oxide (In), tin oxide (Sn), or zinc oxide (Zn); two-component metal oxides such as In-Zn oxides, Sn-Zn oxides, Al-Zn oxides, Zn-Mg oxides, Sn-Mg oxides, In-Mg oxides, or In-Ga oxides; three-component metal oxides such as In-Ga-Zn oxides, In-Al-Zn oxides, In-Sn-Zn oxides, Sn-Ga-Zn oxides, Al-Ga-Zn oxides, Sn-Al-Zn oxides, In-Hf-Zn oxides, In-La-Zn oxides, In-Ce-Zn oxides, In-Pr-Zn oxides, In-Nd-Zn oxides, In-Sm-Zn oxides, In-Eu-Zn oxides, In-Gd-Zn oxides, In-Tb-Zn oxides, In-Dy-Zn oxides, In-Ho-Zn oxides, In-Er-Zn oxides, In-Tm-Zn oxides, In-Yb-Zn oxides, or In-Lu-Zn oxides; or four-component metal oxides such as In-Sn-Ga-Zn oxides, In-Hf-Ga-Zn oxides, In-Al-Ga-Zn oxides, In-Sn-Al-Zn oxides, In-Sn-Hf-Zn oxides, or In-Hf-Al-Zn oxides. For example, the semiconductor layer ACT may include indium-gallium-zinc oxide (IGZO) among the In-Ga-Zn-based oxides.

A gate insulating film GI may be disposed on the semiconductor layer ACT. The gate insulating film GI may have a single-layer or multi-layer structure. The gate insulating film GI may include an inorganic insulating material such as silicon nitride (SiNx), silicon oxide (SiOx), or silicon oxynitride (SiOxNy). The gate insulating film GI may overlap the channel region CH of the semiconductor layer ACT. The gate insulating film GI may not overlap the first region A1 or the second region A2 of the semiconductor layer ACT. However, it is not limited thereto, and the gate insulating film GI may be formed entirely on the substrate SUB.

An oxygen supply layer OS may be disposed on the gate insulating film GI. The oxygen supply layer OS may be disposed between the gate insulating film GI and the gate electrode GAT. The oxygen supply layer OS may control the electrical properties of oxide semiconductors and improve its stability. The oxide semiconductor may prevent oxygen deficiency by supplying the necessary oxygen to the oxide semiconductor. Electrical characteristics of the oxide semiconductor may be optimized by preventing oxygen deficiency.

The oxygen supply layer OS may include silicon dioxide (SiO₂), titanium dioxide (TiO2), aluminum oxide (Al₂O₃), or cerium dioxide (CeO₂).

The gate electrode GAT may be disposed on the oxygen supply layer OS. The gate electrode GAT may overlap the channel region CH of the semiconductor layer ACT. The gate electrode GAT may include a metal material such as molybdenum (Mo), aluminum (Al), copper (Cu), and/or titanium (Ti). After forming the gate electrode GAT, a doping process or plasma treatment may be performed. The portion of the semiconductor layer ACT covered by the gate electrode GAT is not doped or plasma-treated, and the portion of the semiconductor layer ACT not covered by the gate electrode GAT is doped or plasma-treated to have the same characteristics as a conductor.

An interlayer insulating film ILD may be disposed on the gate electrode GAT. The interlayer insulating film ILD may be formed entirely on the substrate SUB. The interlayer insulating film ILD may have a single-layer or multi-layer structure. The interlayer insulating film ILD may include an inorganic insulating material or an organic insulating material.

The first wiring layer SD1 may be disposed on the interlayer insulating film ILD. The first wiring layer SD1 may include the source electrode S and the drain electrode D. A wiring connecting the first region A1 of the semiconductor layer ACT and the source electrode S may be disposed in an opening penetrating the interlayer insulating film ILD. The source electrode S may be connected to the first region A1 of the semiconductor layer ACT. A wiring connecting the second region A2 of the semiconductor layer ACT and the drain electrode D may be disposed in an opening penetrating the interlayer insulating film ILD. The drain electrode D may be connected to the second region A2 of the semiconductor layer ACT. The first wiring layer SD1 is disposed under a first insulating layer PVX1 and may be connected to the first region A1 and the second region A2.

The source electrode S and the drain electrode D may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten, and/or copper (Cu).

The source electrode S, the drain electrode D, the semiconductor layer ACT, and the gate electrode GAT may form one transistor.

A first insulating layer PVX1 may be disposed on the first wiring layer SD1. The first insulating layer PVX1 is a passivation layer formed of an inorganic insulating material and may cover the first wiring layer SD1. The first insulating layer PVX1 may cover the source electrode S and the drain electrode D.

The first organic layer VIA1 may be disposed on the first insulating layer PVX1. The first organic layer VIA1 may be intended to provide a flat upper surface. After forming the first organic layer VIA1, chemical-mechanical polishing may be performed on the upper surface of the first organic layer VIA1. The first organic layer VIA1 may include a photosensitive polyimide, polyimide, polystyrene, polycarbonate, benzocyclobutene (BCB), hexamethyldisiloxane (HMDSO), a general-purpose polymer such as polymethyl methacrylate (PMMA) or polystyrene, a polymer derivative having a phenolic group, an acryl-based polymer, an imide-based polymer, an aryl ether-based polymer, an amide-based polymer, a fluorinated polymer, a p-xylene polymer, or a vinyl alcohol polymer. In FIG. 1, the first organic layer VIA1 is shown as a single layer, but the first organic layer VIA1 may be multilayers.

A second wiring layer SD2 may be disposed on the first organic layer VIA1. The second wiring layer SD2 may be for implementing a display device with higher resolution. Since there is a problem with pixel integration in implementing high resolution with only the first wiring layer SD1, the second wiring layer SD2 may be additionally introduced. The second wiring layer SD2 may include a metal such as Cu or Ti. The second wiring layer SD2 is disposed on the top of the first organic layer VIA1 and may be electrically connected to the first wiring layer SD1 and the first electrode E1.

The first electrode E1 of a light emitting diode ED may be disposed on the second wiring layer SD2. The first electrode E1 may be connected to the source electrode S through the second wiring layer SD2.

The first electrode E1 may be formed of a single layer including a metal material or a transparent conductive oxide, or a multilayer including the metal material and the transparent conductive oxide. The first electrode E1 may include a metal such as silver (Ag), lithium (Li), calcium (Ca), aluminum (Al), magnesium (Mg), or gold (Au), and may also include a transparent conductive oxide (TCO) such as indium tin oxide (ITO) or indium zinc oxide (IZO). For example, the first electrode E1 may have a triple-film structure of indium tin oxide (ITO)/silver (Ag)/indium tin oxide (ITO).

A partition wall PDL may be disposed on the first electrode E1. The partition wall PDL may include organic insulating materials such as general-purpose polymers such as polymethylmethacrylate (PMMA) or polystyrene, a polymer derivative having a phenolic group, an acryl-based polymer, an imide-based polymer, a polyimide, an acryl-based polymer, and a siloxane-based polymer. A pixel opening OP is formed through the partition wall PDL, and the pixel opening OP may be disposed in an area corresponding to the first electrode E1.

A light emitting layer EML may be disposed in the pixel opening OP of the partition wall PDL. The light emitting layer EML may include a material layer that uniquely emits light of primary colors such as red, green, and blue. The light emitting layer EML may have a structure in which multiple layers of materials emitting light of different colors are stacked. The light emitting layer EML is shown as being disposed solely in the pixel opening OP, but is not limited thereto. The light emitting layer EML may be disposed not only in the pixel opening OP but also on the partition wall PDL. That is, the light emitting layer EML may be disposed entirely on the substrate SUB.

A second electrode E2 may be disposed on the light emitting layer EML and on the partition wall PDL. The second electrode E2 may include a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), calcium (Ca), or a transparent conductive oxide (TCO) such as indium tin oxide (ITO) or indium zinc oxide (IZO).

The first electrode E1, the light emitting layer EML, and the second electrode E2 form a light emitting diode ED. Here, the first electrode E1 may be an anode which is a hole injection electrode and the second electrode E2 may be a cathode which is an electron injection electrode. However, the embodiment is not necessarily limited thereto, and depending on the driving method of an organic light emitting display device, the first electrode E1 may be a cathode and the second electrode E2 may be an anode.

Holes and electrons are injected into the light emitting layer EML from the first electrode E1 and the second electrode E2, respectively, and light is emitted when an exciton formed by combining the injected holes and electrons drops from the excited state to the ground state.

Although not shown in the drawings, an encapsulating layer including an inorganic insulating material and an organic insulating material may be disposed on the second electrode, and a filling layer including a filler may be disposed on the encapsulating layer. A cover layer including an insulating material, a color conversion layer, a transmission layer, etc. may be disposed on the filling layer. The color conversion layer may be disposed on some pixels, and the transmission layer may be disposed on other pixels. The color conversion layer may include semiconductor nanocrystals and the semiconductor nanocrystals may include at least one of a phosphor and a quantum dot material that converts incident light into a different color. Quantum dots may control the color of light emitted depending on the particle size, and thus quantum dots may emit various colors of light such as blue, red, and green. The transmission layer may transmit incident light and may include a polymer material.

A display device according to an embodiment may have a second insulating layer PVX2 disposed on the second wiring layer SD2. The second insulating layer PVX2 may completely surround the second wiring layer SD2. At least a portion of the second insulating layer PVX2 may be disposed on the first organic layer VIA1. The second insulating layer PVX2 may protect the second wiring layer SD2 and may include a material that is resistant to moisture. Silicon nitride (SiNx) may be used as the second insulating layer PVX2. Hydrogen content of the display device may increase when forming the second insulating layer PVX2. When the hydrogen content in the display device increases, the first region A1 and the second region A2 of the semiconductor layer ACT may expand and it makes difficult to secure device characteristics.

A second organic layer VIA2 may be formed on the second insulating layer PVX2 to planarize an upper surface of the second wiring layer SD2 and the second insulating layer PVX2. The second organic layer VIA2 may be disposed directly on the second insulating layer PVX2. The second organic layer VIA2, like the first organic layer VIA1, may be formed of photosensitive polyimide, polyimide, or an imide-based polymer.

The first organic layer VIA1 and the second organic layer VIA2 may include a polymer and, due to characteristics of the polymer, gases such as CH and COH may remain within the polymer after coating. In addition, when heat is applied to the first organic layers VIA1 and the second organic layer VIA2 during subsequent processes, gases generated in the first organic layer VIA1 and the second organic layer VIA2 may be discharged. These gases may flow into a display region through the electrodes and causing defects in the display device when the display panel is driven.

If gas flows into the display region, pixel shrinkage may occur. Pixel shrinkage refers to a phenomenon that the actual pixel opening OP area becomes smaller than designed due to the gas flowing into the display region when the pixel is turned on. In order to make the actual pixel opening OP area equal to the designed area when the pixel is turned on, the second insulating layer PVX2 may include a plurality of first openings MP for gas discharge. In addition, the thickness of the first organic layer VIA1 and the second organic layer VIA2 may be adjusted to facilitate gas discharge.

The second insulating layer PVX2 may include the plurality of first openings MP. The plurality of first openings MP may be holes formed by removing the second insulating layer PVX2. Gases such as hydrogen gas may be discharged through the plurality of first openings MP. The plurality of the first openings MP may be filled with the second organic layer VIA2. The plurality of first openings Mp may be filled with the second organic layer VIA2.

A width W of one of the plurality of first openings MP may have a size of 20% to 23% of a width WW of the pixel opening OP in a cross-sectional view. The width W of one of the plurality of first openings MP may be greater than a length I1 of the first region A1 and a length 12 of the second region A2 in a cross-sectional view. At least some of the plurality of first openings MP may be disposed to overlap the first region A1 and the second region A2. At least two or more of the plurality of first openings MP may be disposed to overlap the channel region CH. The plurality of first openings MP may be formed throughout the entire panel region.

The thickness of each of the first organic layer VIA1 and the second organic layer VIA2 may be from about 1.5 μm to about 3 μm. If the thickness of the first organic layer VIA1 and the second organic layer VIA2 exceeds 3 μm, gas discharge may be difficult even if the organic layers are sufficiently cured. Therefore, the thickness of the organic layer may be set relatively thin to facilitate gas discharge.

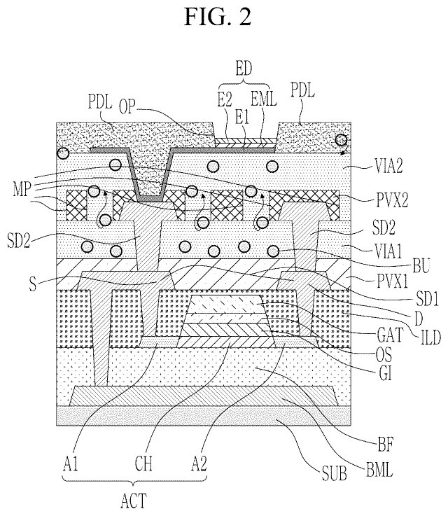

FIG. 2 is a cross-sectional view showing a gas discharge structure of a display device according to an embodiment.

Even after curing of the first organic layer VIA1, a gas BU remaining in the first organic layer VIA1 may be discharged to outside of the display device through the plurality of first openings MP. Therefore, the residual hydrogen and the gas BU in the lower organic layer may be suppressed from moving to the electrode, for example, the second wiring layer SD2. Thus, the second wiring layer SD2 may be protected from the residual hydrogen and the gas BU. The hydrogen content in the display device is also reduced, thus the characteristics of the display device may be prevented from being deteriorated.

The width of the plurality of first openings MP in a cross-sectional view may be adjusted to prevent the inflow of hydrogen and the gas BU from the outside. Even with the plurality of first openings MP, the second wiring layer SD2 may be completely surrounded by the second insulating layer PVX2 to block moisture permeation to the second wiring layer SD2.

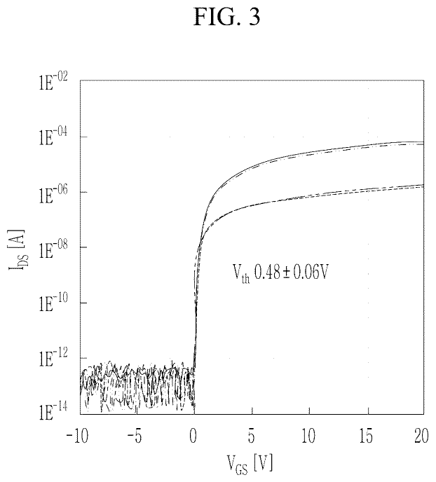

FIG. 3 is a graph showing the performance of a semiconductor layer of a display device according to an embodiment. Referring now to FIG. 1 in FIG. 3, it will be explained that the performance of the semiconductor device of the display device is ensured by including the plurality of first openings MP in the second insulating layer PVX2.

Referring to FIG. 1, the first insulating layer PVX1 and the second insulating layer PVX2 containing silicon nitride may have a high hydrogen content in the layer. Hydrogen in the first insulating layer PVX1 and in the second insulating layer PVX2 may diffused into the semiconductor layer ACT along the first wiring layer SD1 and the second wiring layer SD2. If a large amount of hydrogen flows into the semiconductor layer ACT, the first region A1 which is the source region and the second region A2 which is the drain region of the oxide semiconductor device expand due to the high hydrogen content, and it may be difficult to secure semiconductor device characteristics. Additionally, due to hydrogen gas remained in the first organic layer VIA1 and the second organic layer VIA2, the device characteristics of the oxide semiconductor device may be deteriorated.

The display device according to an embodiment may protect wiring by forming the plurality of openings in the second insulating layer PVX2 to suppress movement of residual hydrogen and gas within the first organic layer VIA1 and the second organic layer VIA2 to the upper electrode layer, thereby securing quality of by blocking external moisture permeation. In addition, by including the plurality of first openings MP, the hydrogen content of the second insulating layer PVX2 itself is reduced, thereby securing the device characteristics of the oxide semiconductor device. In addition, by providing a path for releasing hydrogen and gas remained in the first organic layer VIA1 and the second organic layer VIA2, the hydrogen content may be reduced, thereby preventing the semiconductor layer ACT from becoming conductive.

FIG. 3 is a graph showing the performance of the oxide semiconductor device when the second insulating layer PVX2 includes the plurality of first openings MP. According to FIG. 3, it can be seen that the transistor including the oxide semiconductor operates normally when the second insulating layer includes the plurality of first openings. The X-axis represents a gate-source voltage, represented by V_{GS}. The V_{GS} may have range values between −10 V and 20 V. The Y-axis represents a drain-source current, represented by I_{DS}. The I_{DS} may have range values between 1E⁻¹⁴ A and 1E⁻² A. The graph shows that the I_{DS} increases rapidly when the V_{GS} exceeds Vₜₕ. This indicates the point at which the transistor begins to turn on. In the range from −10 V to 0 V, the I_{DS} has values between 1E⁻¹⁴A and 1E⁻¹²A. This indicates that the transistor is turned off. As the V_{GS} exceeds 0 V, the I_{DS} increases rapidly to a value close to 1E⁻¹A, indicating that the transistor is turned on. The voltage at which the transistor begins to turn on is referred to a threshold voltage Vₜₕ. According to an embodiment, the semiconductor layer ACT of a display device has the threshold voltage Vₜₕ of about 0.48 V. The threshold voltage may have an error range of ±0.06 V. The graph of FIG. 3 shows that when the second insulating layer PVX2 includes the plurality of first openings MP, the transistor operates normally.

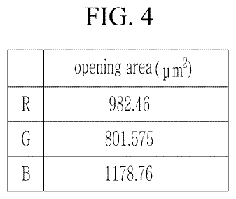

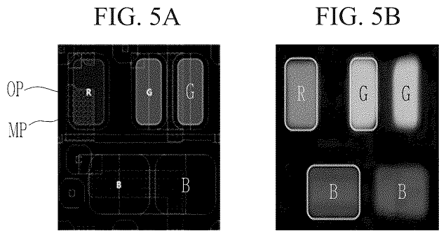

Below, with reference to FIGS. 4 and 5, the pixel opening area of the display device and the image when the actual pixels are turned on will be described.

Referring to FIG. 4, the pixel opening area is 982.46 μum² for the red pixel (R), 801.575 μm² for the green pixel (G), and 1178.76 μM² for the blue pixel (B).

FIG. 5A is an image showing the pixel opening (OP) area of a display device according to an embodiment. FIG. 5B is an image of a display device when pixels are turned on according to an embodiment.

It can be seen that when the second insulating layer PVX2 includes the plurality of first openings MP and the first organic layer VIA1 and the second organic layer VIA2 have a thickness of 1.5 μm, a light emitting region may be maintained as it is designed. It can be seen that the second insulating layer PVX2 includes the plurality of first openings MP and the thicknesses of the first organic layer VIA1 and the second organic layer VIA2 are adjusted to 1.5 μm to prevent pixel shrinkage.

Depending on the stacked structure, such as the first insulating layer PVX1, the first organic layer VIA1 disposed on the first insulating layer PVX1, the second insulating layer PVX2 disposed on the first organic layer VIA1, and the second organic layer VIA2 disposed on the second insulating layer PVX2, gas remaining in the first organic layer VIA1 and in the second organic layer VIA2 may not be discharged sufficiently, cause the gas diffusing into the display region, and cause pixel shrinkage.

A display device according to an embodiment may prevent pixel shrinkage by introducing the second insulating layer to prevent movement of residual hydrogen in an organic layer to the upper electrode layer, thereby protect wiring, and ensure quality of the display device by including the plurality of first openings to provide a path for gas discharge from the organic layer.

In addition, it is possible to reduce the gas content present in the first organic layer VIA1 and the second organic layer VIA2 by reducing the thickness of the first organic layer VIA1 and the second organic layer VIA2. As the thickness of the organic layer is reduced, residual gas is reduced, so that moisture or gas remained within the layer may be discharged easily when the organic layer is cured.

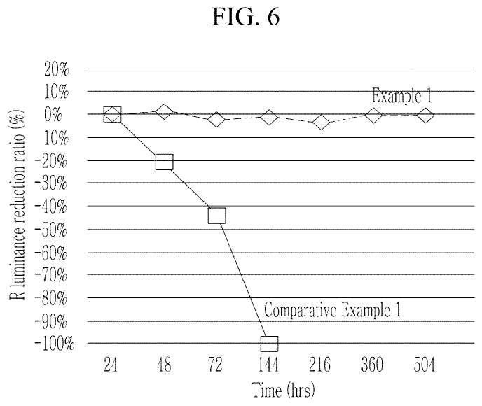

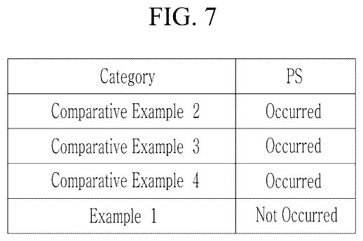

Below, FIGS. 6 and 7 show effect of pixel shrinkage in the comparative examples and examples with reference to FIG. 1.

FIG. 6 is a graph showing the luminance reduction ratio of the red pixel (R) of a display device according to an embodiment.

Referring to FIG. 6 with FIG. 1, the graph of Example 1 shows the luminance reduction ratio of the red pixel (R) when the thickness of the first organic layer VIA1 is 1.5 μm. Example 1 shows that the luminance reduction level of the red pixel (R) remains at 0% not only after 24 hours but also after 504 hours. This is because the thickness of the first organic layer VIA1 is thinner than that in Comparative Example 1, so the amount of remaining hydrogen and gas is small, and the gases may be sufficiently released when the first organic layer VIA1 is cured.

Referring to FIG. 6 with FIG. 1, the graph of Comparative Example 1 shows the luminance reduction ratio of the red pixel (R) when the thickness of the first organic layer VIA1 is 3.0 μm. Other conditions are the same as in Example 1. In Comparative Example 1, the decrease in luminance of the red pixel (R) is 0% as in Example 1 until 24 hours have passed. However, it can be seen that as time passes, hydrogen and gas released from the first organic layer VIA1 diffuse into the display region and cause decreasing of the luminance of the red pixel (R). It can be seen that the luminance of the red pixel (R) decreased by about 20% after 48 hours, decreased by about 45% after 72 hours, and decreased by about 100% after 144 hours.

FIG. 7 is a table showing improvements in pixel shrinkage of a display device according to an embodiment. In FIG. 7, the pixel shrinkage is represented by PS.

According to FIG. 7, Comparative Example 2 is a case where the thicknesses of the first organic layer VIA1 and the second organic layer VIA2 are set to 1.6 μm and the second insulating layer PVX2 is not applied. Although the thicknesses of the first organic layer VIA1 and the second organic layer VIA2 were reduced, the second insulating layer PVX2 was not present to suppress the movement of residual hydrogen and gas within the organic layer to the electrode layer, so hydrogen and gas may diffuse into the display region and cause pixel shrinkage.

Comparative Example 3 is a case where the thicknesses of the first organic layer VIA1 and the second organic layer VIA2 are set to 1.5 μm and the second insulating layer PVX2 is not applied. As in Comparative Example 2, the thicknesses of the first organic layer VIA1 and the second organic layer VIA2 were reduced, but since the second insulating layer PVX2 for suppressing the movement of residual hydrogen and gas within the organic layer to the electrode layer was not present, hydrogen and gas may diffuse into the display region and cause pixel shrinkage.

Comparative Example 4 is a case where the second insulating layer PVX2 is introduced to suppress movement of residual hydrogen and gas within the organic layer to the electrode layer, and the second insulating layer PVX2 includes the plurality of first openings MP for the release of hydrogen and gas, but the thickness of only the second organic layer VIA2 is reduced to 1.5 μm. The thickness of the first organic layer VIA1 was not reduced. In this case, the thickness of the first organic layer VIA1 was thick, so the content of remaining hydrogen and gas was high, and, even when the first organic layer VIA1 was cured, the hydrogen and gas were not sufficiently discharged and cause pixel shrinkage.

Example 1 includes the second insulating layer PVX2 including the plurality of first openings MP, wherein both the first organic layer VIA1 and the second organic layer VIA2 have a thickness of 1.5 μm. The width of the plurality of first openings MP in a cross-sectional view is approximately 21.7% of the pixel opening OP. In this case, the thicknesses of the first organic layer VIA1 and the second organic layer VIA2 are sufficiently thin so that the content of remaining hydrogen and gas is small, and a large amount of hydrogen and gas may be discharged even when curing after coating the organic layer. Hydrogen and gases that are not discharged during curing may be discharged outside the display device through the plurality of first openings MP included in the second insulating layer PVX2. Additionally, the presence of a second insulating layer PVX2 may prevent the movement of hydrogen and gases to the electrode layer. In the case of Example 1, it can be seen that pixel shrinkage PS did not occur, wiring was protected and quality of display device were secured.

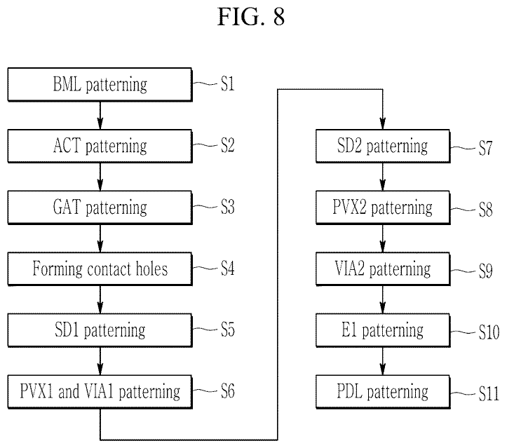

FIG. 8 is a flowchart showing a method of manufacturing a display device according to an embodiment. FIG. 8 will be described with reference to FIG. 1.

Referring to FIG. 1 and FIG. 8, the lower metal layer BML is patterned using a first mask (S1).

Then, the semiconductor layer ACT is patterned using a second mask (S2).

Then, the gate electrode GAT is patterned using a third mask (S3). At this step, the patterning of the gate electrode GAT, the oxygen supply layer OS, and the gate insulating film GI may be formed simultaneously. According to embodiments, the gate electrode GAT and the oxygen supply layer OS may be formed through wet etching, and then the gate insulating film GI may be dry-etched to be patterned.

Then, contact holes are formed using a fourth mask (S4). A contact hole may be formed in the interlayer insulating film ILD and the buffer layer BF for connecting the lower metal layer BML and the source electrode S, and a contact hole for connecting the first region A1 and the source electrode S, and a contact hole for connecting the second region A2 and the drain electrode D may be formed in the interlayer insulating film ILD.

Then, the first wiring layer SD1 is patterned using a fifth mask (S5). At this step, the first wiring layer SD1 may include the source electrode S and the drain electrode D.

After the first wiring layer is patterned, the first insulating layer PVX1 and the first organic layer VIA1 are formed on the patterned first wiring layer SD1.

Then, the first organic layer VIA1 and the first insulating layer PVX1 are patterned using a seventh mask (S6). At this step, the first insulating layer PVX1 is dry-etched to form a contact hole, which is a space for connecting the second wiring layer SD2 and the first wiring layer SD1.

Then, the second wiring layer SD2, which is an additional wiring layer, is patterned through a seventh mask (S7).

After forming the second wiring layer, the second insulating layer PVX2 is patterned using an eighth mask to protect the second wiring layer (S8). The second insulating layer PVX2 is patterned to have the plurality of first openings MP.

After the second insulating layer is formed, the second organic layer VIA2 is patterned using a ninth mask (S9). The second organic layer VIA2 may a substantially planarized upper surface.

Then, the first electrode E1 connected to the second wiring layer SD2 is patterned using a tenth mask (S10).

Then, the partition wall PDL is patterned using an eleventh mask (S11). The pixel opening OP may be formed by patterning the partition wall PDL.

A display device according to an embodiment may be patterned using a total of 11 masks by introducing the second wiring layer as an additional wiring. The display device including the second wiring layer SD2 may be formed by using 11 masks, enabling high-resolution implementation. In addition, when forming the second insulating layer PVX2 to protect the second wiring layer SD2, the plurality of first openings MP may be included to prevent pixel shrinkage, thereby maintaining high resolution.

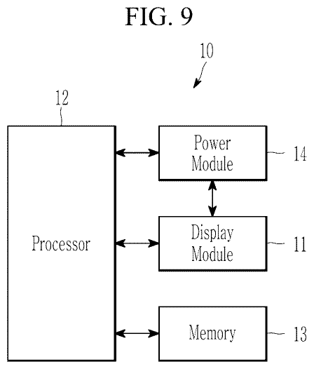

A display device according to an embodiment may be applied to various electronic devices. An electronic device according to an embodiment may include the display device, and may further include modules or devices having additional functions other than the display device. FIG. 9 is a block diagram of an electronic device according to an embodiment. Referring to FIG. 9, the electronic device 10 according to an embodiment may include a display module 11, a processor 12, a memory 13, and a power module 14. The processor 12 may include at least one of a central processing unit (CPU), an application processor (AP), a graphic processing unit (GPU), a communication processor (CP), an image signal processor (ISP), or a controller. The memory 13 may store data information necessary for operations of the processor 12 or the display module 11. When the processor 12 executes an application stored in the memory 13, video data signals and/or input control signals are transmitted to the display module 11, and the display module 11 can process the received signals to output video information through the display screen. The power module 14 may include a power supply module such as a power adapter or battery device, and a power conversion module that converts the power supplied by the power supply module to generate the power necessary for the operation of the electronic device 10. At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

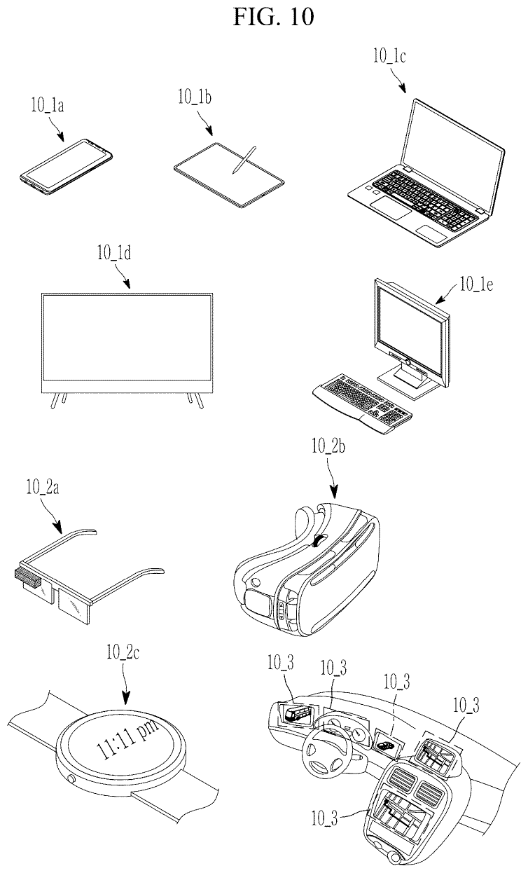

FIG. 10 shows schematic diagrams of electronic devices according to various embodiments. Referring to FIG. 10, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

1. A display device, comprising:
a substrate;
a semiconductor layer disposed on the substrate;
a first insulating layer, a first organic layer, a second insulating layer, and a second organic layer sequentially disposed on the semiconductor layer;
a first electrode disposed on the second organic layer;
a partition wall disposed on the first electrode and including a pixel opening; and
a light emitting layer disposed in the pixel opening,
wherein the second insulating layer includes a plurality of first openings,
wherein the plurality of first openings are filled with the second organic layer, and
wherein the thickness of the first organic layer and the second organic layer is from about 1.5 μm to about 3 μm.

2. The display device of claim 1, wherein the semiconductor layer comprises a channel region, a first region disposed on one side of the channel region, and a second region disposed on another side of the channel region.

3. The display device of claim 2, comprising:
a first wiring layer disposed under the first organic layer and connected to the first region; and
a second wiring layer disposed on the first organic layer and connected to the first wiring layer.

4. The display device of claim 3, wherein
at least some of the plurality of first openings overlap the first region and the second region.

5. The display device of claim 3, wherein
at least two of the plurality of first openings overlap the channel region.

6. The display device of claim 3, wherein a width of one of the plurality of first openings in a cross-sectional view is greater than the lengths of the first region and the second region.

7. The display device of claim 3, wherein a width of one of the plurality of first openings in a cross-sectional view has a size from about 20% to about 23% of the width of the pixel opening.

8. The display device of claim 3, wherein
the first insulating layer and the second insulating layer include silicon nitride.

9. The display device of claim 3, wherein:
the semiconductor layer further comprises a gate insulating film disposed on the channel region;
an oxygen supply layer disposed on the gate insulating film; and
a gate electrode disposed on the oxygen supply layer.

10. The display device of claim 3, wherein
the first wiring layer and the second wiring layer include at least one of Cu, Ti, Al, Pt, Ag, Mg, Ni, or W.

11. The display device of claim 3, wherein
the semiconductor layer comprises an oxide semiconductor.

12. The display device of claim 11, wherein the semiconductor layer comprises at least one of an In-Zn-based oxide, an In-Ga-based oxide, an Sn-Zn-based oxide, an In-Sn-Zn-based oxide, an In-Ga-Zn-based oxide, an Sn-Ga-Zn-based oxide, or an In-Sn-Ga-Zn-based oxide.

13. A display device, comprising:
a substrate;
a semiconductor layer disposed on the substrate;
a first wiring layer, a second wiring layer, a first organic layer, a second organic layer, and an insulating layer disposed on the semiconductor layer;
a first electrode disposed on the first organic layer;
a partition wall disposed on the first electrode and including an opening; and
a light emitting layer disposed in the pixel opening,
wherein the semiconductor layer comprises:
a channel region; and
a first region disposed on one side of the channel region and a second region disposed on another side of the channel region,
wherein the first wiring layer is connected to the first region under the first organic layer,
wherein the second wiring layer is connected to the first wiring layer, and
wherein the thickness of the first organic layer and the second organic layer is about 1.5 μm to about 3 μm.

14. The display device of claim 13, wherein the insulating layer comprises a first insulating layer and a second insulating layer, the second insulating layer comprises a plurality of first openings, and the plurality of first openings are filled with the second organic layer.

15. The display device of claim 14, wherein
the first insulating layer is disposed between the semiconductor layer and the first organic layer, and the second insulating layer is disposed between the first organic layer and the second organic layer.

16. The display device of claim 14, wherein
at least some of the plurality of first openings overlap the first region and the second region.

17. The display device of claim 14, wherein
at least two of the plurality of first openings overlap the channel region.

18. The display device of claim 14, wherein a width of one of the plurality of first openings in a cross-sectional view is greater than the lengths of the first region and the second region.

19. The display device of claim 14, wherein a width of one of the plurality of first openings in a cross-sectional view has a size from about 20% to about 23% of the width of the pixel opening.

20. An electronic device comprising:
a memory;
a processor executing an application stored in the memory; and
a display device comprising a display module outputting video information provided by the application,
wherein the display device comprising:
a substrate;
a semiconductor layer disposed on the substrate;
a first insulating layer, a first organic layer, a second insulating layer, and a second organic layer sequentially disposed on the semiconductor layer;
a first electrode disposed on the second organic layer;
a partition wall disposed on the first electrode and including a pixel opening; and
a light emitting layer disposed in the pixel opening,
wherein the second insulating layer includes a plurality of first openings, the plurality of first openings are filled with the second organic layer, and the thickness of the first organic layer and the second organic layer is from about 1.5 μm to about 3 μm.
